(19) United States
(12) Patent Application Publication
(10) Pub. No.: US 2019/0013355 A1
(43) Pub. Date: Jan. 10, 2019

(54) SEMICONDUCTOR DEVICE

(71) Applicant: TOSHIBA MEMORY CORPORATION, Tokyo (JP)

(72) Inventors: Hikari TAJIMA, Mitaka (JP); Takashi IZUMIDA, Kamakura Kanagawa (JP); Takahisa KANEMURA, Yokohama Kanagawa (JP); Hiroki TOKUHIRA, Kawasaki Kanagawa (JP)

(73) Assignee: TOSHIBA MEMORY CORPORATION, Tokyo (JP)

(21) Appl. No.: 15/907,146

(22) Filed: Feb. 27, 2018

(30) Foreign Application Priority Data
Jul. 4, 2017 (JP) 2017-131424

(51) Int. Cl. H01L 27/24; H01L 29/78

(52) U.S. Cl. CPC H01L 27/2454; H01L 27/2481; G11C 2213/81; G11C 2213/71; H01L 29/7827

(57) ABSTRACT

According to one embodiment, the first lines extend in a first direction. The first gate electrodes extend in a second direction intersecting with the first direction. The second lines extend in a third direction orthogonal to the first direction and the second direction. The semiconductor portion is disposed between the first gate electrodes, and between one of the first lines and one of the second lines, and connected to the first line and the second line. The semiconductor portion has a column shape. The semiconductor portion includes a plurality of channels isolated in a direction orthogonal to the third direction. The second gate electrode is provided between the channels. The insulating film is provided between the semiconductor portion and the first gate electrode, and between the semiconductor portion and the second gate electrode.

### CROSS-REFERENCE TO RELATED APPLICATION

This application is based upon and claims the benefit of priority from Japanese Patent Application No. 2017-131424, filed on Jul. 4, 2017; the entire contents of which are incorporated herein by reference.

### FIELD

Embodiments described herein relate generally to a semiconductor device.

### BACKGROUND

A semiconductor device having a vertical bit line (VBL) structure has been proposed. The device includes a plurality of bit lines extending in columns on a substrate and disposed in a matrix, a plurality of global bit lines disposed between the bit lines and the substrate and extending in a direction parallel to a major surface of the substrate, and vertical transistors each disposed between one of the global bit lines and one of the bit lines.

The vertical transistors function as selection transistors that turn connections between the global bit lines and the bit lines on and off. The pitch of the plurality of selection transistors depends on the pitch of the plurality of global bit lines and the pitch of the plurality of bit lines, and thus selection transistors in an on state and selection transistors in an off state are arranged at such a limited pitch. With such a structure, it is often difficult to increase the on-off ratio of the selection transistors.

### BRIEF DESCRIPTION OF THE DRAWINGS

FIG. 1 is a schematic perspective view of a semiconductor device of an embodiment;

FIG. 2 is a schematic cross-sectional view of a semiconductor device of an embodiment;

FIG. 3 is a schematic perspective view of a selection transistor of a semiconductor device of an embodiment;

FIG. 4 is a cross-sectional view taken from a line A-A′ in FIG. 3;

FIGS. 5A and 5B are schematic perspective views of a selection transistor of a semiconductor device of an embodiment;

FIG. 6 is a schematic perspective view of a selection transistor of a semiconductor device of an embodiment;

FIG. 7 is a schematic perspective view of a selection transistor of a semiconductor device of an embodiment;

FIG. 8 is a cross-sectional view taken from a line A-A′ in FIG. 7;

FIG. 9 is a schematic perspective view of a selection transistor of a semiconductor device of an embodiment;

FIG. 10A is a cross-sectional view taken from a line A-A′ in FIG. 9, and FIG. 10B is a cross-sectional view showing another example of FIG. 10A;

FIGS. 11A and 11B are Id-Vg characteristic graphs of a selection transistor;

FIG. 12 is a Id-Vg characteristic graph of a selection transistor;

FIG. 13A to FIG. 16B are schematic perspective views showing a method for manufacturing a selection transistor of an embodiment; and

FIG. 17 is a schematic cross-sectional view, corresponding to FIG. 4, FIG. 8, FIG. 10A and FIG. 10B, of a selection transistor of a comparative example.

### DETAILED DESCRIPTION

According to one embodiment, a semiconductor device includes a plurality of first lines, a plurality of first gate electrodes, a plurality of second lines, a semiconductor portion, a second gate, and an insulating film. The first lines extend in a first direction. The first gate electrodes extend in a second direction intersecting with the first direction. The second lines extend in a third direction orthogonal to the first direction and the second direction. The semiconductor portion is disposed between the first gate electrodes, and between one of the first lines and one of the second lines, and connected to the first line and the second line. The semiconductor portion has a column shape. The semiconductor portion includes a plurality of channels isolated in a direction orthogonal to the third direction. The second gate electrode is provided between the channels. The insulating film is provided between the semiconductor portion and the first gate electrode, and between the semiconductor portion and the second gate electrode.

Embodiments will be described below with reference to drawings. Note that the same reference numerals are applied to the same elements in each drawing.

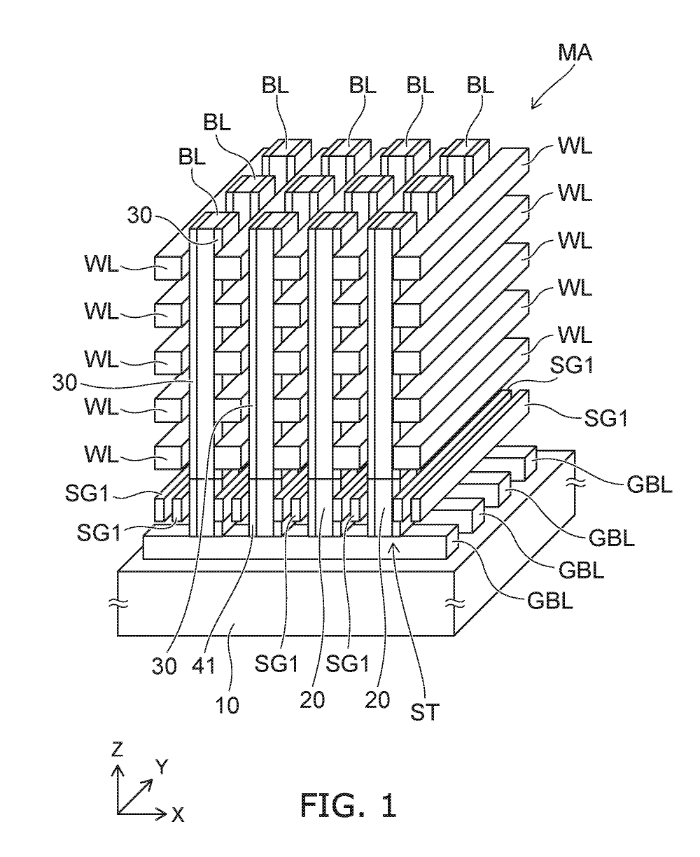

FIG. 1 is a schematic perspective view of a semiconductor device of an embodiment.

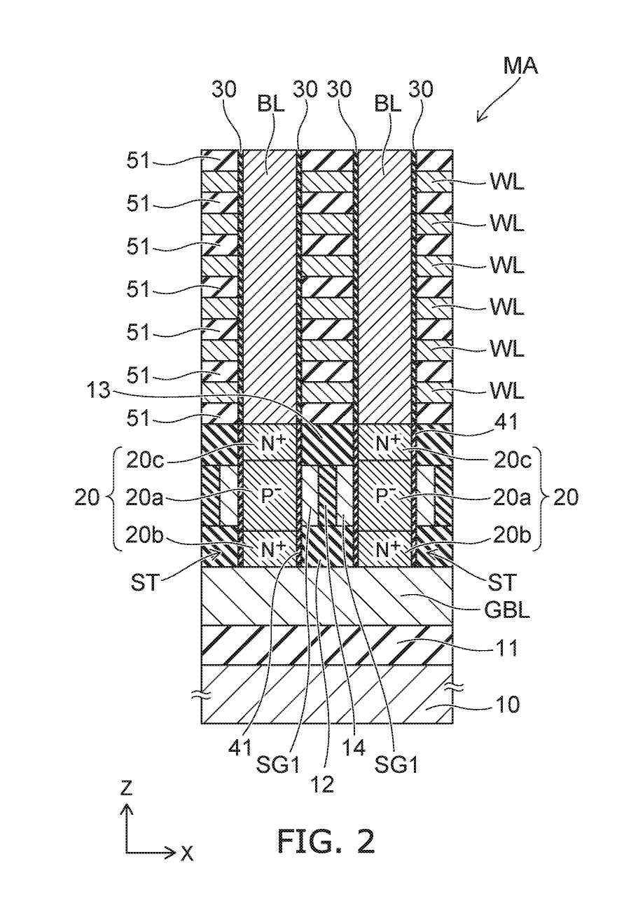

FIG. 2 is a schematic cross-sectional view of the semiconductor device of the embodiment.

In FIG. 1, an X-direction and a Y-direction are orthogonal in a plane parallel to a major surface of a substrate 10. A direction perpendicular to the major surface of the substrate 10 and orthogonal to the X-direction and the Y-direction is a Z-direction. The X-direction, Y-direction, and Z-direction in the other drawings correspond to the X-direction, Y-direction, and Z-direction in FIG. 1.

The embodiment will be described using a semiconductor storage device having a memory cell array MA with a three-dimensional structure as an example of a semiconductor device.

The memory cell array MA is provided on the substrate 10. The memory cell array MA includes a plurality of bit lines (first lines) BL and a plurality of word lines WL.

The bit lines BL extend in column shapes in the Z-direction. The plurality of bit lines BL are separated from each other in the X-direction and the Y-direction, and disposed in a matrix.

The word lines WL extend in the Y-direction on the sides of the bit lines BL. The plurality of word lines WL are stacked in the Z-direction so as to be separated from each other, and are arranged separated from each other in the X-direction. A row of a plurality of bit lines BL arranged in the Y-direction is disposed between word lines WL adjacent in the X-direction.

Insulating layers 51, illustrated in FIG. 2, are provided between word lines WL adjacent in the Z-direction. Insulating layers that are not illustrated are provided between bit lines BL adjacent in the Y-direction.

A variable resistance film 30, for example, is provided between the bit lines BL and the word lines WL as a memory film. The variable resistance film 30 is provided, for example, on side surfaces of the bit lines BL that oppose the word lines WL, and is continuous in the Z-direction along the bit lines BL.

The variable resistance film 30 is capable of electrically switching between a state of relatively low resistance and a state of relatively high resistance, and stores data in a non-volatile manner.

For example, when the variable resistance film 30 is in the high-resistance state and a voltage not less than a set magnitude is applied via the bit lines BL and the word lines WL, the variable resistance film 30 transitions to the low-resistance state. On the other hand, when the variable resistance film 30 is in the low-resistance state and current not less than a set magnitude flows via the bit lines BL and the word lines WL, the variable resistance film 30 transitions to the high-resistance state.

As illustrated in FIG. 1, a plurality of global bit lines (first lines) GBL are provided upon the substrate 10. An insulating layer 11, illustrated in FIG. 2, is provided between the substrate 10 and the global bit lines GBL.

As illustrated in FIG. 1, the plurality of global bit lines GBL extend in the X-direction and are separated from each other in the Y-direction. The pitch at which the plurality of global bit lines GBL are arranged in the Y-direction is the same as the pitch at which the plurality of bit lines BL are arranged in the Y-direction.

The bit lines BL, the word lines WL, and the global bit lines GBL are wires containing a metal, for example, as their major components. Alternatively, the bit lines BL, the word lines WL, and the global bit lines GBL may be wires containing an impurity-doped semiconductor, for example, as their major components.

A plurality of selection transistors ST are disposed between the memory cell array MA and the plurality of global bit lines GBL.

The selection transistors ST are vertical transistors in which current flows in a direction substantially perpendicular to the major surface of the substrate 10 (i.e., the vertical direction).

The plurality of selection transistors ST are disposed corresponding to the plurality of bit lines BL. A single selection transistor ST includes a column-shaped semiconductor portion (or semiconductor pillar) 20 disposed between a single bit line BL and a single global bit line GBL. The semiconductor portion 20 extends in the Z-direction between the single bit line BL and the single global bit line GBL, and is connected to the bit line BL and the global bit line GBL.

The semiconductor portion 20 is formed as, for example, a square column, a circular column, an elliptical column, a circular cone, or an elliptical cone.

A plurality of the semiconductor portions 20 are disposed in a matrix, for example, at the same pitch as the pitch at which the plurality of bit lines BL are disposed. A plurality of the semiconductor portions 20 are arranged in the X-direction on a single global bit line GBL.

As illustrated in FIG. 2, each semiconductor portion 20 includes a first semiconductor region 20b, a second semiconductor region 20c, and a channel 20a provided between the first semiconductor region 20b and the second semiconductor region 20c. One of the first semiconductor region 20b and the second semiconductor region 20c corresponds to a drain region, and the other to a source region, of the vertical transistor.

The first semiconductor region 20b and the second semiconductor region 20c are N-type silicon regions, and the channel 20a is a P-type silicon region, for example. The N-type impurity concentration of the first semiconductor region 20b and the N-type impurity concentration of the second semiconductor region 20c are higher than the P-type impurity concentration of the channel 20a. The channel 20a is not limited to a P-type silicon region, and may instead be an N-type silicon region having a lower N-type impurity concentration than the N-type impurity concentration of the first semiconductor region 20b and the N-type impurity concentration of the second semiconductor region 20c.

When a gate potential not less than a threshold value is supplied to gate electrodes SG1 and SG2, which will be described later, an N-type inversion layer is formed in the channel 20a, and the selection transistor ST turns on.

The first semiconductor regions 20b contact the global bit lines GBL, and the second semiconductor regions 20c contact the bit lines BL.

First gate electrodes SG1 extend in the Y-direction on the sides of the plurality of semiconductor portions 20 arranged in the Y-direction. The first gate electrodes SG1 are disposed between semiconductor portions 20 adjacent in the X-direction. The plurality of first gate electrodes SG1 are arranged so as to be separated from each other in the X-direction. A pair of the first gate electrodes SG1 extends in the Y-direction with the semiconductor portion 20 located therebetween in the X-direction, and the first gate electrodes SG1 in the pair oppose respective side surfaces of the semiconductor portion 20 in the X-direction.

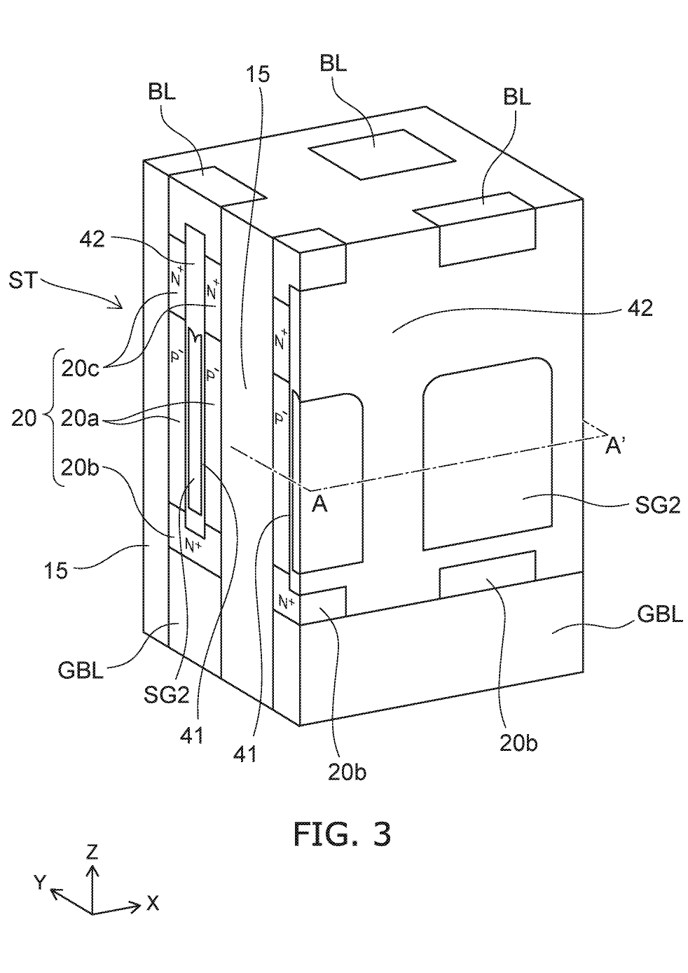

FIG. 3 is a schematic perspective view of the selection transistor ST.

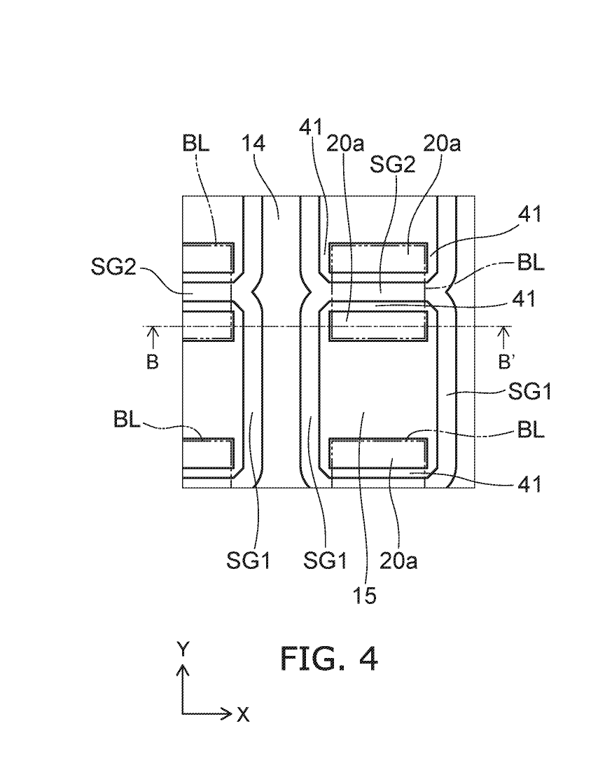

FIG. 4 is a cross-sectional view taken from the line A-A′ in FIG. 3.

As illustrated in FIGS. 3 and 4, the semiconductor portion 20 disposed between a single global bit line GBL and a single bit line BL includes a plurality of the channels 20a physically isolated from each other.

The one bit line BL positioned above the plurality of channels 20a disposed between a single global bit line GBL and a single bit line BL is indicated by the double-dot single-dash line in FIG. 4

The plurality of channels 20a disposed below a single bit line BL and connected in common to that bit line BL are isolated in a direction parallel to the XY plane. In the example illustrated in FIG. 4, the plurality of channels 20a are isolated in the Y-direction.

As illustrated in FIG. 3, bottom end portions of the plurality of channels 20a, on the global bit line GBL side, are connected to each other through the first semiconductor region 20b. In other words, a single first semiconductor region 20b is provided in common for a plurality of channels 20a between a single global bit line GBL and a single bit line BL.

In the example illustrated in FIG. 3, the second semiconductor regions 20c are isolated as a plurality in the same manner as the channels 20a, and the second semiconductor regions 20c are provided above corresponding ones of the plurality of channels 20a.

In addition to the above-described first gate electrode SG1, the selection transistor ST further includes a second gate electrode SG2.

The second gate electrode SG2 is provided between two channels 20a isolated in the Y-direction. As illustrated in FIG. 4, the second gate electrode SG2 extends in the X-direction between two isolated channels 20a.

A plurality of channels 20a, arranged isolated from each other in the Y-direction, are disposed between a pair of first gate electrodes SG1 adjacent in the X-direction and extending in the Y-direction. End portions of the second gate electrode SG2 extending in the X-direction so as to divide the channels 20a in the Y-direction are connected to the above-described pair of first gate electrodes SG1.

In other words, the pair of first gate electrodes SG1 on both sides, in the X-direction, of the plurality of channels 20a isolated in the Y-direction are connected to each other by the second gate electrode SG2 extending in the X-direction between that pair of first gate electrodes SG1.

The first gate electrode SG1 and the second gate electrode SG2 are provided as an integrated entity formed from the same material (e.g., a material containing impurity-doped polycrystalline silicon or a metal).

End portions of the first gate electrode SG1 in the Y-direction are, for example, connected to a control circuit via contacts (not illustrated) disposed in regions that do not overlap with the memory cell array MA.

An insulating film (gate insulating film) 41 is provided on side surfaces of the semiconductor portion 20. Accordingly, the insulating film 41 is provided between the channel 20a and the first gate electrode SG1 and between the channel 20a and the second gate electrode SG2. The insulating film 41 is a silicon oxide film, for example. The insulating film 41 is also provided between a bottom end of the second gate electrode SG2 and the first semiconductor region 20b.

As illustrated in FIG. 2, a bottom end of the first gate electrode SG1 is located further on the channel 20a side than a border between the first semiconductor region 20b and the channel 20a, and a top end of the first gate electrode SG1 is located further on the channel 20a side than a border between the second semiconductor region 20c and the channel 20a.

As illustrated in FIG. 3, a bottom end of the second gate electrode SG2 is located further on the channel 20a side than a border between the first semiconductor region 20b and the channel 20a, and a top end of the second gate electrode SG2 is located further on the channel 20a side than a border between the second semiconductor region 20c and the channel 20a.

This positional relationship between the gate electrodes SG1 and SG2 and the high-impurity concentration semiconductor regions 20b and 20c suppresses what is known as Gate Induced Drain Leakage (GIDL), which is leak current produced by direct tunneling resulting from a high potential difference between the semiconductor regions 20b and 20c and the gate electrodes SG1 and SG2 when the selection transistor ST turns off.

As illustrated in FIGS. 2 and 4, an insulating layer 14 is provided between first gate electrodes SG1 separated in the X-direction between semiconductor portions 20 adjacent in the X-direction. As illustrated in FIGS. 3 and 4, an insulating layer 15 is provided between semiconductor portions 20 adjacent in the Y-direction located below different bit lines BL. As illustrated in FIG. 3, an insulating layer 42 is provided on the second gate electrode SG2.

As illustrated in FIG. 2, an insulating layer 12 is provided between the global bit lines GBL and the first gate electrodes SG1, and an insulating layer 13 is provided between the first gate electrodes SG1 and the stacked body of the memory cell array MA.

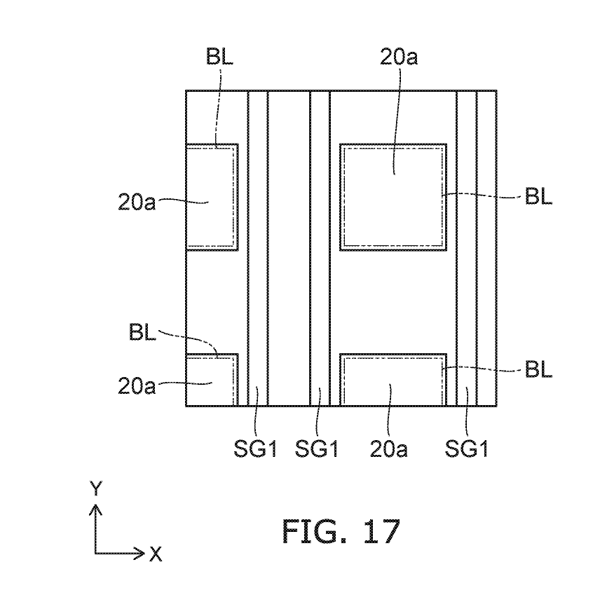

FIG. 17 is a schematic cross-sectional view, corresponding to FIG. 4, of a selection transistor of a comparative example.

In the selection transistor of the comparative example, a single column-shaped channel 20a is disposed below a single bit line BL, and the channel 20a disposed below that single bit line BL is not isolated.

In the comparative example, only the first gate electrodes SG1 are provided as gate electrodes, disposed to the sides of the channels 20a and extending in the Y-direction. The second gate electrode SG2, disposed to divide the channel 20a disposed below a single bit line BL, is not provided.

The pitches of the plurality of bit lines BL in the X-direction and in the Y-direction are the same in both the embodiment illustrated in FIG. 4 and the comparative example illustrated in FIG. 17. In other words, the pitches of the plurality of selection transistors in the X-direction and in the Y-direction are the same in both the embodiment illustrated in FIG. 4 and the comparative example illustrated in FIG. 17.

According to the selection transistor of the embodiment, the channel 20a disposed below a single bit line BL has a plurality of isolated parts, and the second gate electrode SG2 is disposed between the isolated channels 20a. Accordingly, the channel width (the area over which the gate electrode opposes the channel) can be made wider than in the comparative example. Increasing the channel width improves the on-state current. Disposing the second gate electrode SG2 between the channels 20a not only improves the gate controllability, but also suppresses the amount of GIDL produced and makes it possible to increase an on-state current/off-state current ratio.

The embodiment illustrated in FIG. 4 corresponds to a structure in which the column-shaped channels 20a of the comparative example illustrated in FIG. 17 are divided in two in the Y-direction, and each isolated channel 20a is thinner than the channel 20a of the comparative example.

Making the channel 20a thinner in this manner suppresses a current path that cannot be controlled by the gate electrode (a current path near the axial center of the column-shaped channel 20a illustrated in FIG. 17), which improves the gate controllability. Furthermore, improving the gate controllability shortens the channel length (the length of the channel 20a in the Z-direction), which leads to an improvement in on-state current. Shortening the channel length also leads to the suppression of processing irregularities when forming the channel 20a.

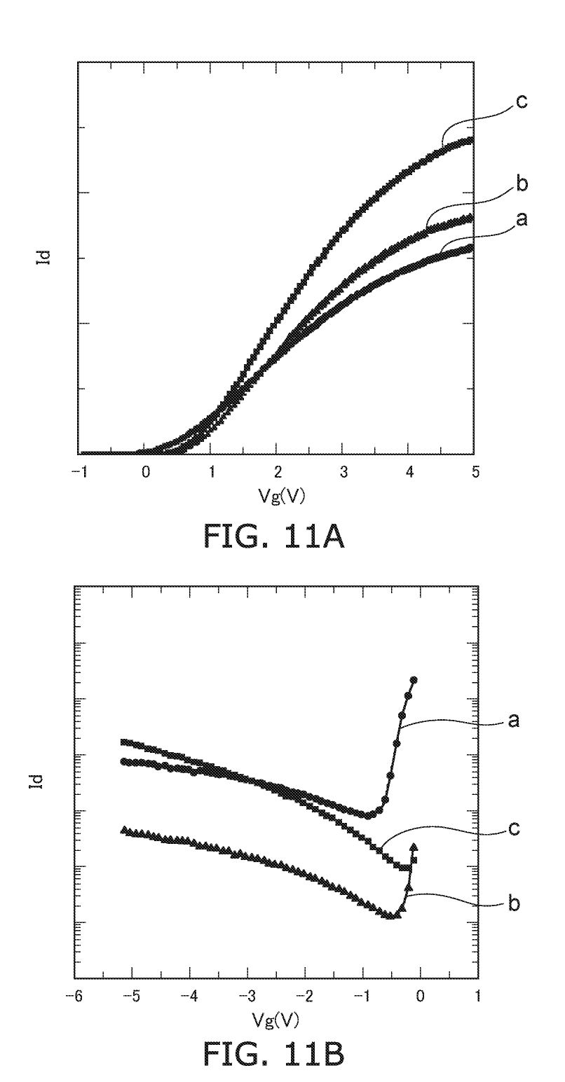

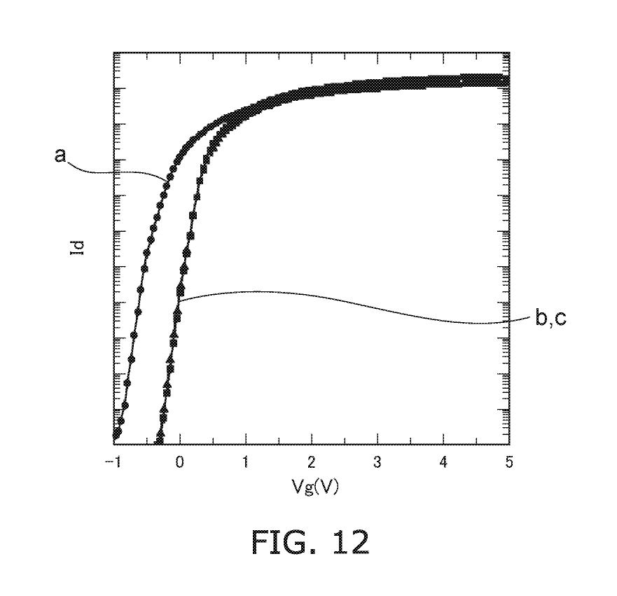

FIGS. 11A, 11B, and 12 are Id-Vg characteristic graphs expressing relationships between a gate potential Vg and a drain current Id of a vertical selection transistor. The vertical axis in FIG. 11A represents a linear scale, whereas the vertical axis in FIGS. 11B and 12 represents a log scale.

“a” represents the characteristics of the selection transistor of the comparative example illustrated in FIG. 17, and “b,” the characteristics of the selection transistor of the first embodiment illustrated in FIGS. 3 and 4.

According to the graph in FIG. 11A, comparing the characteristics when Vg is 3 V shows that Id (on-state current) in the first embodiment is about 1.2 times Id in the comparative example.

According to the graph in FIG. 11B, the first embodiment has successfully reduced off-state current, including a GIDL component, by an amount equivalent to one digit or more than in the comparative example.

According to the graph in FIG. 12, the first embodiment has a higher threshold voltage than in the comparative example. This indicates the possibility that the P-type impurity (e.g. boron) concentration (amount) of the channel 20a of the first embodiment can be set lower than the P-type impurity (e.g. boron) concentration (amount) of the channel 20a of the comparative example. This can lead to a reduction in threshold voltage irregularities caused by irregularities in the impurity concentrations (amounts) of the channels 20a. Reducing irregularities in the threshold voltage also reduces irregularities in the on-state current and off-state current.

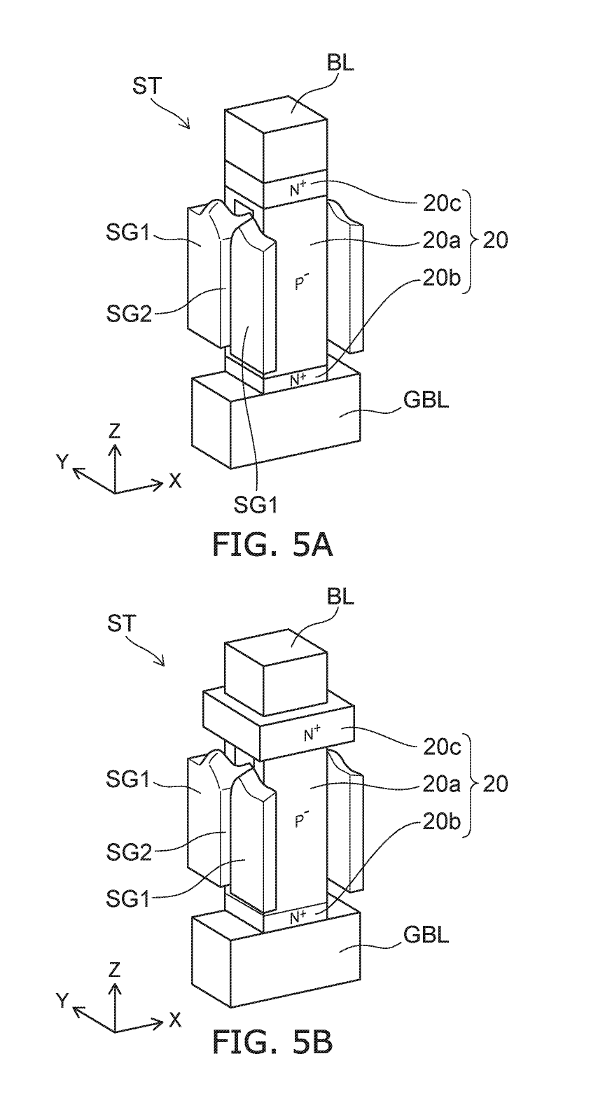

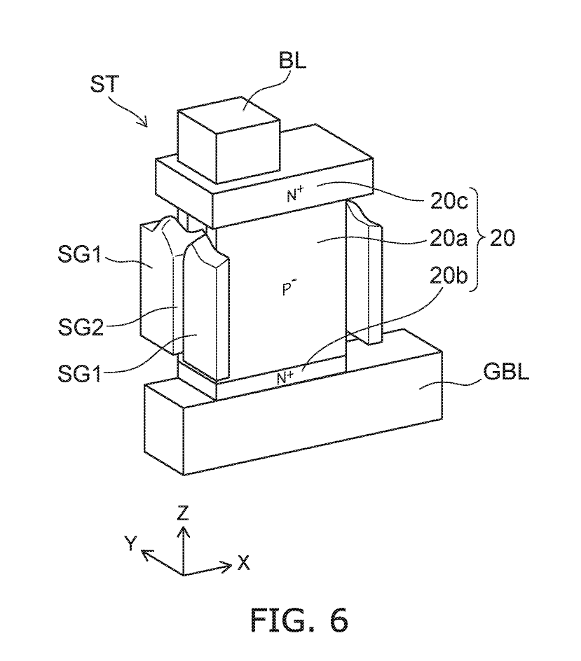

FIGS. 5A, 5B, and 6 are schematic perspective views of other examples of a selection transistor of embodiments.

In the examples illustrated in FIGS. 5A, 5B, and 6, the upper end portions of the plurality of channels 20a on the bit line BL side are connected to each other by the second semiconductor region 20c. In other words, a single second semiconductor region 20c is provided in common for a plurality of channels 20a between a single global bit line GBL and a single bit line BL.

Furthermore, in the examples illustrated in FIGS. 5B and 6, the size of the second semiconductor region 20c in the X-direction is greater than the size, in the X-direction, of the portion of the semiconductor portion 20 in which the plurality of channels 20a are arranged. The size of the second semiconductor region 20c in the Y-direction is greater than the size, in the Y-direction, of the portion of the semiconductor portion 20 in which the plurality of channels 20a are arranged.

Such a configuration increases the contact area between the bit lines BL and the semiconductor portions 20, and reduces the contact resistance between the two. This furthermore increases the acceptable range of positional skew between the semiconductor portions 20 and the bit lines BL.

Furthermore, in the example illustrated in FIG. 6, the semiconductor portion 20 has a greater size in the X-direction than in the Y-direction, and the semiconductor portion 20 is formed in the shape of a parallelepiped having a longer direction in the direction following the global bit lines GBL (the X-direction).

Such a configuration increases the contact area between the global bit lines GBL and the semiconductor portions 20, and reduces the contact resistance between the two. This furthermore increases the acceptable range of positional skew between the semiconductor portions 20 and the bit lines BL in the X-direction.

Other embodiments will be described next. The descriptions will focus on parts different from the first embodiment; in some cases, elements same as those in the first embodiment will be assigned the same reference signs, and descriptions thereof will be omitted.

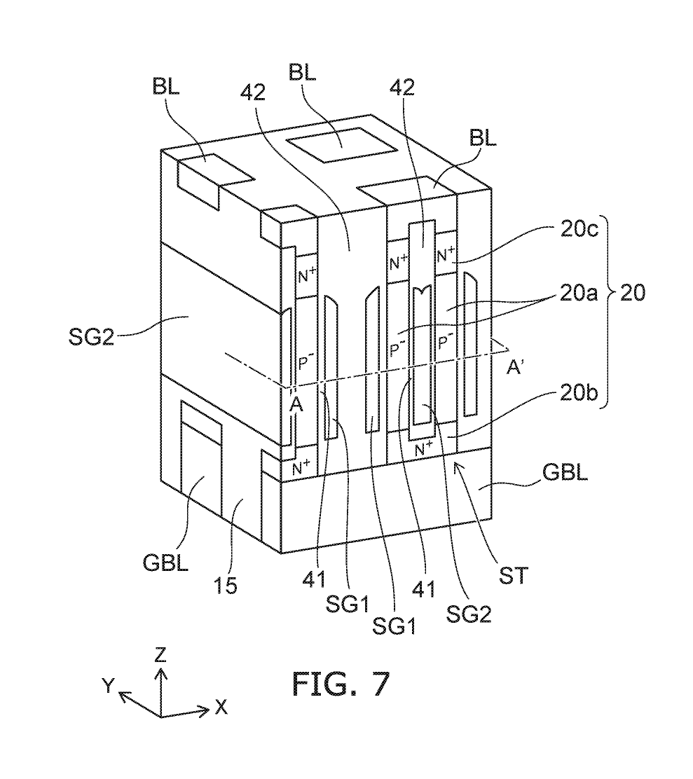

FIG. 7 is a schematic perspective view of a selection transistor ST of a second embodiment.

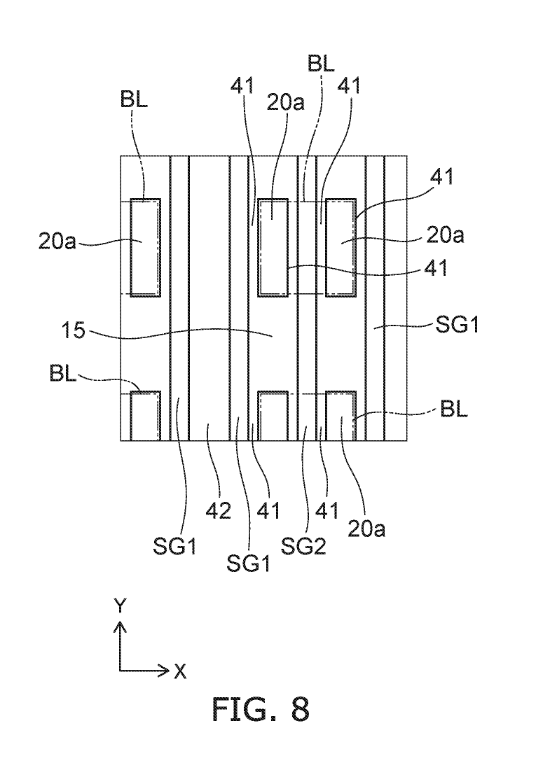

FIG. 8 is a cross-sectional view taken from the line A-A′ in FIG. 7.

In the selection transistor ST of the second embodiment as well, the semiconductor portion 20 disposed between a single global bit line GBL and a single bit line BL includes a plurality of the channels 20a physically isolated from each other.

The plurality of channels 20a disposed below a single bit line BL and connected in common to that bit line BL are isolated in the X-direction, as illustrated in FIG. 8.

Furthermore, in addition to the above-described first gate electrode SG1, the selection transistor ST further includes the second gate electrode SG2. The second gate electrode SG2 is provided between two channels 20a isolated in the X-direction. As illustrated in FIG. 8, the second gate electrode SG2 extends in the Y-direction between two isolated channels 20a. The first gate electrode SG1 and the second gate electrode SG2 extend parallel to each other.

A plurality of channels 20a, arranged isolated from each other in the X-direction, are disposed between a pair of first gate electrodes SG1 adjacent in the X-direction and extending in the Y-direction. The second gate electrode SG2 extends in the Y-direction so as to divide the channel 20a in the X-direction.

The insulating film (gate insulating film) 41 is provided on side surfaces of the semiconductor portion 20. Accordingly, the insulating film 41 is provided between the channel 20a and the first gate electrode SG1 and between the channel 20a and the second gate electrode SG2.

The insulating layer 42 is provided between first gate electrodes SG1 separated in the X-direction between semiconductor portions 20 adjacent in the X-direction. The insulating layer 15 is provided between semiconductor portions 20 adjacent in the Y-direction located below different bit lines BL. The insulating layer 42 is provided on the first gate electrode SG1 and the second gate electrode SG2.

The pitches of the plurality of bit lines BL in the X-direction and in the Y-direction are the same in both the second embodiment illustrated in FIGS. 7 and 8 and the above-described comparative example illustrated in FIG. 17. In other words, the pitches of the plurality of selection transistors in the X-direction and in the Y-direction are the same in both the second embodiment and the comparative example illustrated in FIG. 17.

According to the selection transistor of the second embodiment, the channel 20a disposed below a single bit line BL has a plurality of isolated parts, and the second gate electrode SG2 is disposed between the isolated channels 20a. Accordingly, the channel width (the area over which the gate electrode opposes the channel) can be made wider than in the comparative example. Increasing the channel width improves the on-state current. Disposing the second gate electrode SG2 between the channels 20a not only improves the gate controllability, but also suppresses the amount of GIDL produced and makes it possible to increase an on-state current/off-state current ratio.

The second embodiment corresponds to a structure in which the column-shaped channels 20a of the comparative example illustrated in FIG. 17 are divided in two in the X-direction, and each isolated channel 20a is thinner than the channel 20a of the comparative example.

Making the channel 20a thinner in this manner suppresses a current path that cannot be controlled by the gate electrode (a current path near the axial center of the column-shaped channel 20a illustrated in FIG. 17), which improves the gate controllability. Furthermore, improving the gate controllability shortens the channel length (the length of the channel 20a in the Z-direction), which leads to an improvement in on-state current. Shortening the channel length also leads to the suppression of processing irregularities when forming the channel 20a.

In the above-described Id-Vg characteristic graphs illustrated in FIGS. 11A, 11B, and 12, “c” expresses the characteristics of the selection transistor of the second embodiment.

According to the graph in FIG. 11A, comparing the characteristics when Vg is 3 V shows that Id (on-state current) in the second embodiment is about 1.6 times Id in the comparative example.

According to the graph in FIG. 11B, the second embodiment has successfully reduced off-state current, including a GIDL component, by an amount equivalent to one digit or more than in the comparative example.

According to the graph in FIG. 12, the second embodiment has a higher threshold voltage than in the comparative example. This indicates the possibility that the P-type impurity (e.g. boron) concentration (amount) of the channel 20a of the second embodiment can be set lower than the P-type impurity (e.g. boron) concentration (amount) of the channel 20a of the comparative example. This can lead to a reduction in threshold voltage irregularities caused by irregularities in the impurity concentrations (amounts) of the channels 20a. Reducing irregularities in the threshold voltage also reduces irregularities in the on-state current and off-state current.

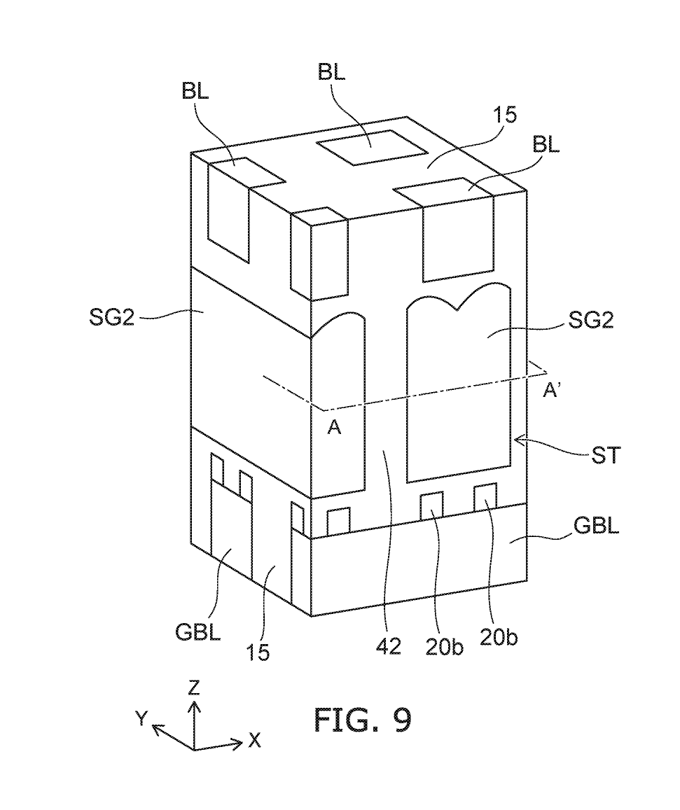

FIG. 9 is a schematic perspective view of a selection transistor ST of a third embodiment.

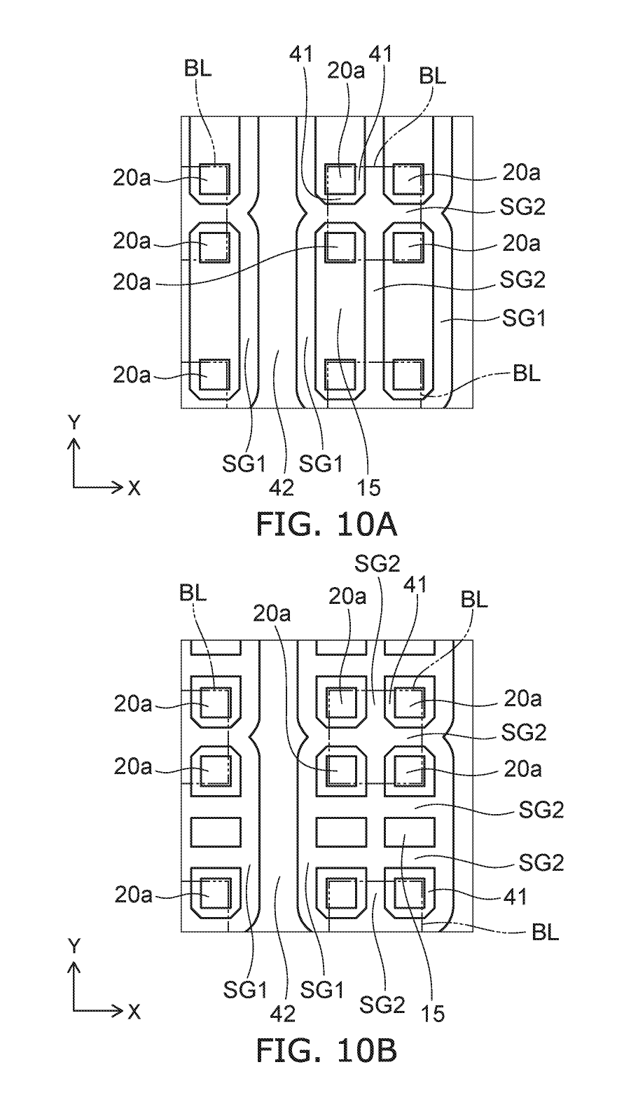

FIG. 10A is a cross-sectional view taken from the line A-A′ in FIG. 9.

In the selection transistor ST of the third embodiment as well, the semiconductor portion 20 disposed between a single global bit line GBL and a single bit line BL includes a plurality (four) of the channels 20a physically isolated from each other.

The plurality of channels 20a disposed below a single bit line BL and connected in common to that bit line BL are isolated in the X-direction and the Y-direction, as illustrated in FIG. 10A.

Furthermore, in addition to the above-described first gate electrode SG1, the selection transistor ST further includes the second gate electrode SG2. The second gate electrodes SG2 are provided between two channels 20a isolated in the X-direction, and between two channels 20a isolated in the Y-direction.

As illustrated in FIG. 10A, the second gate electrodes SG2 extend in the X-direction and the Y-direction between four isolated channels 20a. The second gate electrode SG2 extending in the X-direction and the second gate electrode SG2 extending in the Y-direction are formed as an integrated entity in a cross shape, for example, and furthermore, both ends of the second gate electrode SG2 extending in the X-direction are connected to the first gate electrodes SG1 in an integral manner.

A plurality of channels 20a, arranged isolated from each other in the X-direction and the Y-direction, are disposed between a pair of first gate electrodes SG1 adjacent in the X-direction and extending in the Y-direction. The second gate electrodes SG2 extend in the Y-direction and the X-direction so as to divide the channel 20a in the X-direction and the Y-direction.

The insulating film (gate insulating film) 41 is provided on side surfaces of the semiconductor portion 20. Accordingly, the insulating film 41 is provided between the channel 20a and the first gate electrode SG1 and between the channel 20a and the second gate electrode SG2.

The insulating layer 42 is provided between first gate electrodes SG1 separated in the X-direction between semiconductor portions 20 adjacent in the X-direction. The insulating layer 15 is provided between semiconductor portions 20 adjacent in the Y-direction located below different bit lines BL. The insulating layer 42 is provided on the second gate electrodes SG2.

The pitches of the plurality of bit lines BL in the X-direction and in the Y-direction are the same in both the third embodiment illustrated in FIGS. 9 and 10A and the above-described comparative example illustrated in FIG. 17. In other words, the pitches of the plurality of selection transistors in the X-direction and in the Y-direction are the same in both the third embodiment and the comparative example illustrated in FIG. 17.

According to the selection transistor of the third embodiment, the channel 20a disposed below a single bit line BL has a plurality of isolated parts, and the second gate electrode SG2 is disposed between the isolated channels 20a. Accordingly, the channel width (the area over which the gate electrode opposes the channel) can be made wider than in the comparative example. Increasing the channel width improves the on-state current. Disposing the second gate electrode SG2 between the channels 20a not only improves the gate controllability, but also suppresses the amount of GIDL produced and makes it possible to increase an on-state current/off-state current ratio.

The third embodiment corresponds to a structure in which the column-shaped channels 20a of the comparative example illustrated in FIG. 17 are divided in four in the X-direction and the Y-direction, and each isolated channel 20a is thinner than the channel 20a of the comparative example.

Making the channel 20a thinner in this manner suppresses a current path that cannot be controlled by the gate electrode (a current path near the axial center of the column-shaped channel 20a illustrated in FIG. 17), which improves the gate controllability. Furthermore, improving the gate controllability shortens the channel length (the length of the channel 20a in the Z-direction), which leads to an improvement in on-state current. Shortening the channel length also leads to the suppression of processing irregularities when forming the channel 20a.

FIG. 10B is a diagram corresponding to FIG. 10A, illustrating a variation on the selection transistor of the third embodiment.

The example illustrated in FIG. 10B has the following feature in addition to the configuration illustrated in FIG. 10A. That is, the second gate electrode SG2 extending in the X-direction is also provided between the channel 20a provided below one of two bit lines BL adjacent in the Y-direction and the channel 20a provided below the other of the stated bit lines BL. Such a structure further increases the gate controllability.

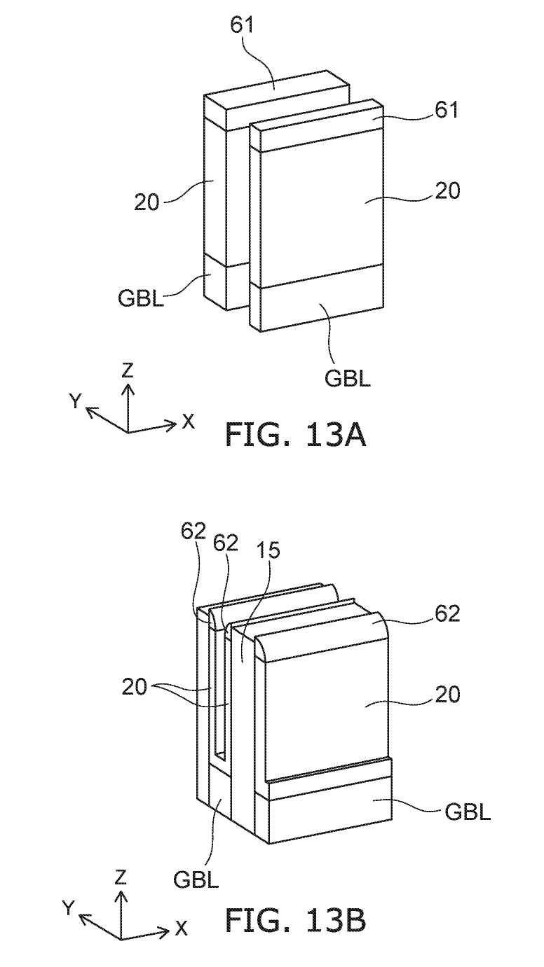

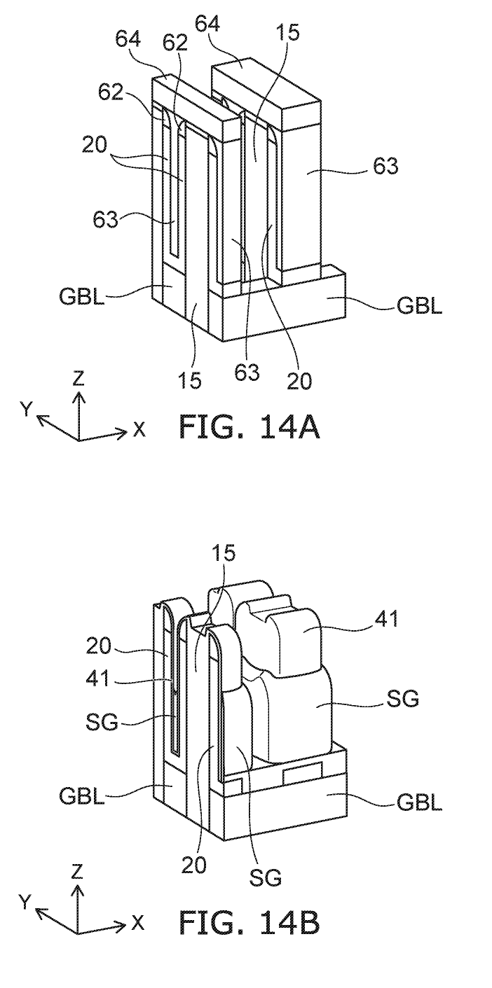

FIGS. 13A to 14B are schematic perspective views illustrating a method of forming the selection transistor ST of the first embodiment as described above with reference to FIGS. 3 and 4. The substrate 10 is not illustrated.

After a material layer of the semiconductor portions 20 is formed upon a material layer of the global bit lines GBL, the semiconductor portions 20 and the global bit lines GBL are processed into line shapes extending in the X-direction as illustrated in FIG. 13A, through, for example, reactive ion etching (RIE) using a mask 61.

The insulating layer 15 is embedded between the global bit lines GBL isolated in the Y-direction and between the semiconductor portions 20 isolated in the Y-direction, as illustrated in FIG. 13B. The mask 61 on the semiconductor portions 20 (illustrated in FIG. 13A) is then removed, and a mask 62 is once again formed on the semiconductor portions 20.

The insulating layer 15 projects further upward than the top surfaces of the semiconductor portions 20, and the top surface of the insulating layer 15 is positioned higher than the top surfaces of the semiconductor portions 20. The mask 62 (e.g. a silicon nitride film) is formed along the top surfaces of the semiconductor portions 20, the side surfaces of the portions of the insulating layer 15 above the semiconductor portions 20, and the top surface of the insulating layer 15. RIE is then carried out on the mask 62, and the portions of the mask 62 formed on the side surfaces of the insulating layer 15 and extending in the X-direction remain as side wall portions.

The semiconductor portions 20 are isolated in the Y-direction through RIE using the side wall portions of the mask 62. Bottoms of the semiconductor portions 20 are not isolated, and the semiconductor portions 20 are processed into U shapes.

A dummy material (or a sacrificial film) 63, indicated in FIG. 14A, is embedded in the isolated portions of the semiconductor portions 20.

Then, the semiconductor portions 20, the insulating layer 15, and the dummy material 63 are isolated in the X-direction through RIE using a mask 64.

After the dummy material 63 has been removed, the insulating film (gate insulating film) 41 is formed on the surfaces of the semiconductor portions 20 as illustrated in FIG. 14B.

After the insulating film 41 has been formed, a gate electrode material SG (e.g. polycrystalline silicon) is deposited on the side walls of the semiconductor portions 20 on the X-direction sides and on the inner sides of the U-shaped semiconductor portions 20, and the gate electrode material SG is then etched back. By forming the gate electrode material SG, the first gate electrode SG1 and the second gate electrode SG2 illustrated in FIG. 4 are formed as an integrated entity.

The insulating layer 42 illustrated in FIG. 3 is then embedded between the semiconductor portions 20 isolated in the X-direction. The insulating layer 42 is also formed on the second gate electrode SG2 provided on the inner sides of the U-shaped semiconductor portions 20.

The process of forming the memory cell array MA is continued thereafter.

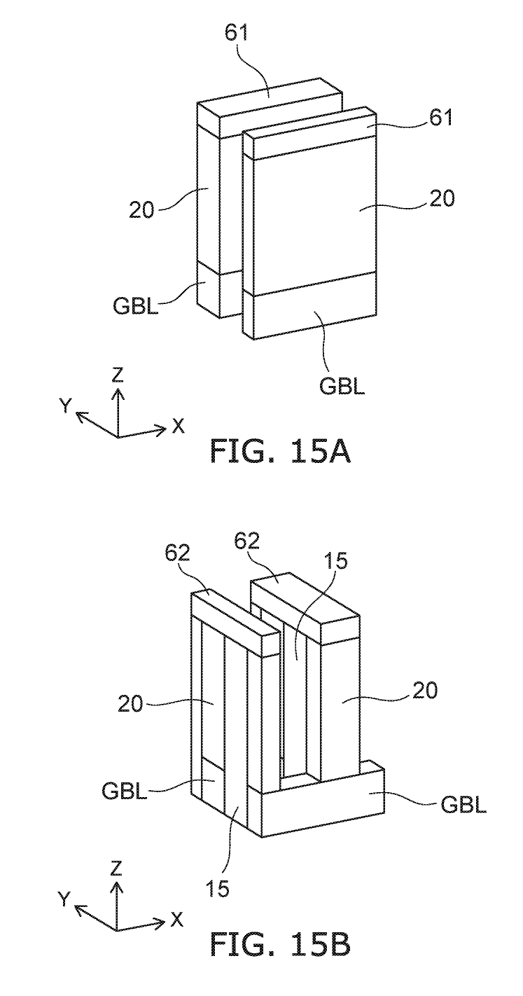

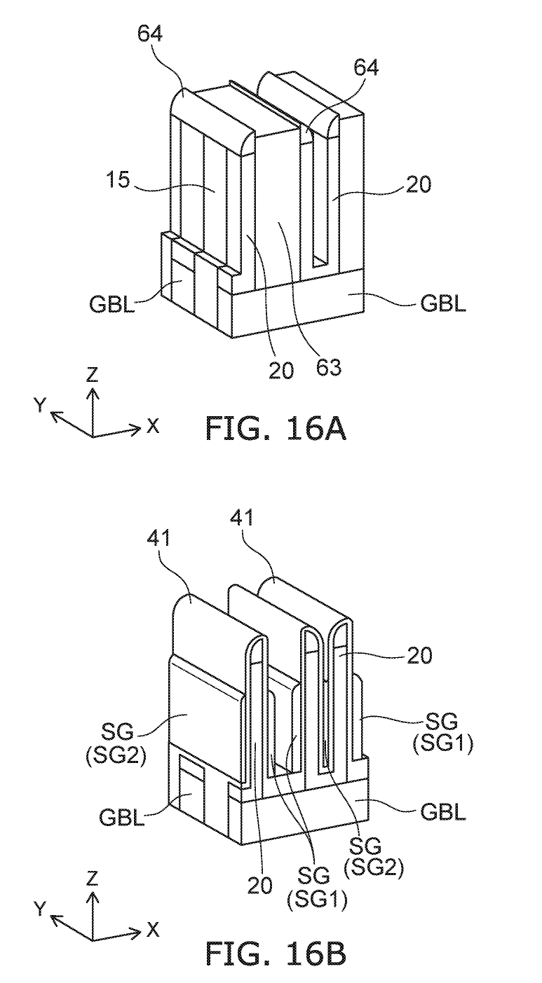

FIGS. 15A to 16B are schematic perspective views illustrating a method of forming the selection transistor ST of the second embodiment as described above with reference to FIGS. 7 and 8. The substrate 10 is not illustrated.

After a material layer of the semiconductor portions 20 is formed upon a material layer of the global bit lines GBL, the semiconductor portions 20 and the global bit lines GBL are processed into line shapes extending in the X-direction as illustrated in FIG. 15A, through, for example, RIE using the mask 61.

The insulating layer 15 is embedded between the global bit lines GBL isolated in the Y-direction and between the semiconductor portions 20 isolated in the Y-direction, as illustrated in FIG. 15B. Then, the semiconductor portions 20 and the insulating layer 15 are isolated in the X-direction through RIE using the mask 62.

The dummy material 63 is then embedded between the semiconductor portions 20 isolated in the X-direction and between the insulating layers 15 isolated in the Y-direction, as illustrated in FIG. 16A.

The mask 62 (illustrated in FIG. 15B) is then removed, and the mask 64 is formed on the semiconductor portions 20 and the insulating layer 15.

The dummy material 63 projects further upward than the top surfaces of the semiconductor portions 20 and the top surface of the insulating layer 15, and the top surface of the dummy material 63 is positioned higher than the top surfaces of the semiconductor portions 20 and the top surface of the insulating layer 15. The mask 64 (e.g. a silicon nitride film) is formed along the top surfaces of the semiconductor portions 20, the top surface of the insulating layer 15, the side surfaces of the portions of the dummy material 63 above the semiconductor portions 20 and the insulating layer 15, and the top surface of the dummy material 63. RIE is then carried out on the mask 64, and the portions of the mask 64 formed on the side surfaces of the dummy material 63 and extending in the Y-direction remain as side wall portions.

The semiconductor portions 20 are isolated in the X-direction through RIE using the side wall portions of the mask 64. The insulating layer 15 is also isolated in the X-direction. Bottoms of the semiconductor portions 20 are not isolated, and the semiconductor portions 20 are processed into U shapes.

Then, the insulating film (gate insulating film) 41 is formed on the surfaces of the semiconductor portions 20 as illustrated in FIG. 16B.

After the insulating film 41 has been formed, a gate electrode material SG (e.g. polycrystalline silicon) is deposited on the side walls of the semiconductor portions 20 on the X-direction sides and on the inner sides of the U-shaped semiconductor portions 20, and the gate electrode material SG is then etched back. By forming the gate electrode material SG, the first gate electrode SG1 and the second gate electrode SG2 are formed simultaneously.

The insulating layer 42 illustrated in FIG. 8 is then embedded between the semiconductor portions 20 isolated in the X-direction. The insulating layer 42 covers the gate electrode material SG as illustrated in FIG. 7.

The selection transistor of the third embodiment illustrated in FIGS. 9, 10A, and 10B can be formed by combining the above-described processes of forming the selection transistor of the first embodiment and of forming the selection transistor of the second embodiment.

According to embodiments, the second gate electrode extending in the first direction is also provided between a channel provided below one of two of the second lines adjacent in the second direction and a channel provided below the other of the second lines.

According to embodiments, the semiconductor portion includes an N-type first semiconductor region connected to the first line, an N-type second semiconductor region connected to the second line, and a P-type one of the channels provided between the first semiconductor region and the second semiconductor region.

According to embodiments, one of the first semiconductor regions is provided in common to the plurality of channels between one of the first lines and one of the second lines.

According to embodiments, one of the second semiconductor regions is provided in common to the plurality of channels between one of the first lines and one of the second lines.

According to embodiments, a size of the second semiconductor region in the first direction is greater than a size, in the first direction, of a portion of the semiconductor portion in which the plurality of channels are arranged.

According to embodiments, a size of the second semiconductor region in the second direction is greater than a size, in the second direction, of a portion of the semiconductor portion in which the plurality of channels are arranged.

According to embodiments, a bottom end of the first gate electrode is positioned further on the side where the channels are located than a border between the first semiconductor region and the channels, and a top end of the first gate electrode is positioned further on the side where the channels are located than a border between the second semiconductor region and the channels.

According to embodiments, a bottom end of the second gate electrode is positioned further on the side where the channels are located than a border between the first semiconductor region and the channels, and a top end of the second gate electrode is positioned further on the side where the channels are located than a border between the second semiconductor region and the channels.

According to embodiments, a plurality of word lines extending in the second direction on sides of the second line and separated from each other in the first direction and the third direction, and a memory film provided between the word lines and the second lines, are further included.

According to embodiments, the memory film is a variable resistance film.

According to embodiments, the variable resistance film is provided on side surfaces of the second lines and is continuous in the third direction.

According to embodiments, the plurality of second lines are disposed in a matrix extending in the first direction and the second direction.

According to embodiments, the first gate electrode and the second gate electrode are provided as an integrated entity formed from the same material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a plurality of first lines extending in a first direction;
a plurality of first gate electrodes extending in a second direction intersecting with the first direction;
a plurality of second lines extending in a third direction orthogonal to the first direction and the second direction;
a semiconductor portion disposed between the first gate electrodes, and between one of the first lines and one of the second lines, and connected to the first line and the second line, the semiconductor portion having a column shape, the semiconductor portion including a plurality of channels isolated in a direction orthogonal to the third direction;
a second gate electrode provided between the channels; and
an insulating film provided between the semiconductor portion and the first gate electrode, and between the semiconductor portion and the second gate electrode.

2. The device according to claim 1, wherein
the channels are isolated in the second direction; and
the second gate electrode extends in the first direction.

3. The device according to claim 2, wherein
an end portion of the second gate electrode extending in the first direction is connected to the first gate electrode.

4. The device according to claim 1, wherein
the channels are isolated in the first direction; and
the second gate electrode extends in the second direction.

5. The device according to claim 1, wherein
the channels are isolated in the first direction and the second direction; and
the second gate electrode extends in the first direction and the second direction.

6. The device according to claim 5, wherein
the second gate electrode extending in the first direction is also provided between a channel provided below one of two of the second lines adjacent in the second direction and a channel provided below the other of the second lines.

7. The device according to claim 1, wherein
bottom end portions of the channels on a first line side are connected to each other.

8. The device according to claim 1, wherein
upper end portions of the channels on a second line side are connected to each other.

9. The device according to claim 1, wherein
the semiconductor portion includes:
an N-type first semiconductor region connected to the first line;
an N-type second semiconductor region connected to the second line; and
a P-type one of the channels provided between the first semiconductor region and the second semiconductor region.

10. The device according to claim 9, wherein
one of the first semiconductor regions is provided in common to the plurality of channels between one of the first lines and one of the second lines.

11. The device according to claim 9, wherein
one of the second semiconductor regions is provided in common to the plurality of channels between one of the first lines and one of the second lines.

12. The device according to claim 11, wherein
a size of the second semiconductor region in the first direction is greater than a size, in the first direction, of a portion of the semiconductor portion in which the channels are arranged.

13. The device according to claim 11, wherein
a size of the second semiconductor region in the second direction is greater than a size, in the second direction, of a portion of the semiconductor portion in which the channels are arranged.

14. The device according to claim 9, wherein
a bottom end of the first gate electrode is positioned further on the side where the channels are located than a border between the first semiconductor region and the channels; and
a top end of the first gate electrode is positioned further on the side where the channels are located than a border between the second semiconductor region and the channels.

15. The device according to claim 9, wherein
a bottom end of the second gate electrode is positioned further on the side where the channels are located than a border between the first semiconductor region and the channels; and
a top end of the second gate electrode is positioned further on the side where the channels are located than a border between the second semiconductor region and the channels.

16. The device according to claim 1, further comprising:
a plurality of word lines extending in the second direction on sides of the second line, and separated from each other in the first direction and the third direction; and
a memory film provided between the word lines and the second lines.

17. The device according to claim 16, wherein
the memory film is a variable resistance film.

18. The device according to claim 17, wherein
the variable resistance film is provided on side surfaces of the second lines and is continuous in the third direction.

19. The device according to claim 1, wherein
the second lines are disposed in a matrix extending in the first direction and the second direction.

20. The device according to claim 1, wherein
the first gate electrode and the second gate electrode are provided as an integrated entity formed from the same material.
